(19) United States
(12) Patent Application Publication
(10) Pub. No.: US 2019/0049532 A1
(43) Pub. Date: Feb. 14, 2019

(54) RF POWER AMPLIFIER FOR MAGNETIC RESONANCE IMAGING

(71) Applicant: TAO WANG, EINDHOVEN (NL)

(72) Inventor: TAO WANG, EINDHOVEN (NL)

(73) Assignee: Koninkijke Phillips N.V., Eindhoven (NL)

(21) Appl. No.: 15/764,413

(22) PCT Filed: Sep. 23, 2016
(86) PCT No.: PCT/EP2016/072623

§ 371 Date: Mar. 29, 2018

(30) Foreign Application Priority Data
Sep. 30, 2015 (CN) PCT/CN2015/091240
Jan. 22, 2016 (EP) 16152340.2

(51) Int. Cl. G01R 33/36; H03F 3/19; H03F 1/02; H03F 1/56; H03F 3/21

(52) U.S. Cl. CPC G01R 33/3614; G01R 33/3628; H03F 3/19; H03F 1/0288; H03F 1/565; H03F 2203/21142; H03F 2200/451; H03F 2200/301; H03F 2200/387; H03F 2203/21139; H03F 3/211

(57) ABSTRACT

An embodiment of the present invention provides a RF power amplifier. The RF power amplifier comprises an RF input distribution network, multiple amplifiers and a signal combining network. The RF input distribution network is configured to divide an input RF signal into a main input signal and an auxiliary input signal. The multiple amplifiers are coupled in parallel to the RF input distribution network and configured to amplify the main and auxiliary input signals respectively by a main amplifier contributing a larger portion of the output power of the RF power amplifier and an auxiliary amplifier contributing a smaller portion of the output power of the RF amplifier. Each of the main and auxiliary amplifiers is selected from the amplifiers according to an impedance Z_{L} of the transmit coil. A loading level of the main amplifier is modulated to alleviate loading mismatch condition of the main amplifier by adjusting current contributions from the main amplifier and the auxiliary amplifier according to the impedance Z_{L} of the transmit coil. The signal combining network is configured to combine the main amplified signal and the auxiliary amplified signal into an output signal to drive the transmit coil.

### FIELD OF THE INVENTION

The invention relates to the field of magnetic resonance imaging (MRI), and more particularly to RF power amplifiers for RF pulse excitation in MRI systems.

### BACKGROUND OF THE INVENTION

Magnetic resonance imaging (MRI) and spectroscopy (MRS) systems are often used for the examination and treatment of patients. By such a system, the nuclear spins of the body tissue to be examined are aligned by a static main magnetic field B₀ and are excited by transverse magnetic fields B₁ oscillating in the radiofrequency band. In imaging, relaxation signals are exposed to gradient magnetic fields to localize the resultant resonance. The relaxation signals are received and reconstructed into a single or multi-dimensional image. In spectroscopy, information about the composition of the tissue is carried in the frequency component of the resonance signals.

An RF coil system provides the transmission of RF pulse signals and the reception of resonance signals. In addition to the RF coil system which is permanently built into the imaging apparatus, special purpose coils can be flexibly arranged around or in a specific region to be examined. Special purpose coils are designed to optimize the signal-to-noise ratio (SNR), particularly in situations where homogeneous excitation and high sensitivity detection is required.

The RF transmit coil that radiates the radio frequency pulse signals is connected to an RF power amplifier. Several problems arise from connecting the RF transmit coil to the RF power amplifier at higher field strengths. Typically, the RF power amplifier is pre-tuned to a predetermined optimum impedance, e.g. 50 ohms. An impedance matching circuit between the RF power amplifier and the RF transmit coil matches the impedance looking into the RF transmit coil to the predetermined optimum impedance. However, the loading on the RF transmit coil may vary considerably, depending on the size and composition of the object being imaged which is inherently coupled to the RF transmit coil, thereby changing the impedance of the RF transmit coil and hence leading to an impedance mismatch.

Due to the impedance mismatch, a maximum available output power and a power efficiency of the RF power amplifier may be significantly degraded. Furthermore, a severe impedance mismatch may increase the RF power reflected back to the output of the RF power amplifier, so that the risk of damaging the RF power amplifier cannot be neglected. To address problems due to the impedance mismatch, a circulator, or isolator, has been introduced, which makes the optimum impedance always seen by the RF power amplifier. However, high power circulators, such as those used in MRI systems, are expensive to design and manufacture. They require ferrite materials and complicated heat exchange systems that include heat sinks and expensive thermally conductive materials with low dielectric constants to prevent arching.

US20140062603A1 discloses a load modulation network for a power amplifier. The load modulation network is arranged to operate with transmission line characteristic impedance by a current ratio of each of a plurality of amplifying modules of the power amplifier. By taking the current ratio between sub-amplifiers into consideration, characteristic impedances in the load modulation network can be devised to overcome imperfect load modulation exists in conventional design. Accordingly, efficiency and output power can be enhanced.

### SUMMARY OF THE INVENTION

It is an object of the invention to provide a new RF power module, which is automatically adapted to various load conditions to deliver the desired Output power level in a more efficient fashion.

Embodiments of the invention provide a RF power module, a method for driving a transmit coil using the RF power module, and a MRI system embedded with the RF power module in the independent claims. Embodiments are given in the dependent claims.

An embodiment of the present invention provides a RF power module. The RF power module comprises an RF input distribution network, multiple amplifiers and a signal combining network. The RF input distribution network is configured to divide an input RF signal into a main input signal and an auxiliary input signal. The multiple amplifiers are coupled in parallel to the RF input distribution network and configured to amplify the main and auxiliary input signals respectively by a main amplifier and an auxiliary amplifier. Each of the main and auxiliary amplifiers is selected from the amplifiers according to an impedance Z₁ of the transmit coil, which is also the load impedance seen by the RF power module. Each amplifier has a predetermined optimum load impedance Z_{OP}, e.g., 50Ω, into which the amplifier is designed to deliver the maximum output power. The signal combining network is configured to combine the main amplified signal and the auxiliary amplified signal into an output signal to drive the transmit coil. With different current contributions from the main amplifier and the auxiliary amplifier, the loading seen by the main amplifier, which contributes more output power, is modulated to an impedance level that can alleviate the loading mismatch condition. Although the loading seen by the auxiliary amplifier is not matched to the predetermined optimum load impedance Z_{OP}, the auxiliary amplifier only delivers a relatively small portion of the output power, and thereby the effect of a loading mismatch at the auxiliary amplifier is negligible.

According to one embodiment of the present invention, the RF power module further comprises a controller coupled to the RF input distribution network and the amplifier section. The controller is configured to adjust current contributions respectively from the main amplifier and the auxiliary amplifier according to the impedance Z_{L} of the transmit coil to obtain the predetermined optimum load impedance Z_{OP} on the main amplifier.

Advantageously, the load seen by the main amplifier, which contributes more output power, is modulated to the predetermined optimum load impedance Z_{OP}, which allows the main amplifier to always operate in the load matching condition regardless of a variation in the impedance Z_{L} of the transmit coil, e.g., arising from different size and/or weight of the patients to be examined.

According to another embodiment of the present invention, the RF power module further comprises a first amplifier configured to provide a first current I1 to the transmit coil through a common node, and a second amplifier configured to provide a second current I2 to the transmit coil sequentially through an impedance transformer and the common node. The first and second amplifiers form the amplifier section, and the impedance transformer and the common node form the signal combining network. Advantageously, different current paths of the first current I1 and the second current I2 allow the modulation of current contributions, thereby adjusting the load seen by the first and second amplifier.

According to yet another embodiment of the present invention, the first amplifier is selected as the main amplifier and the second amplifier is selected as the auxiliary amplifier if the impedance Z_{L} is smaller than Z_{OP}. The second amplifier is selected as the main amplifier and the first amplifier is selected as the auxiliary amplifier if the impedance Z_{L} is larger than Z_{OP}.

According to yet another embodiment of the present invention, a characteristic impedance Z_{TL} of the impedance transformer is substantially equal to (Z_{OP}*Z_{LH})^{1/2}. Z_{LH} represents a predetermined upper limit of a range of the impedance Z_{L}.

According to yet another embodiment of the present invention, the RF power module further comprises a directional coupler coupled to the transmit coil and used to detect the impedance Z_{L} of the transmit coil during a pre-scan of the MRI system, and a controller configured to control a division of the RF input signal and bias voltages of the first and second amplifiers to adjust a current ratio between the current I₁ and the current I₂ according to the detected impedance Z_{L}.

According to yet another embodiment of the present invention, the main amplifier is biased to operate in Class AB mode and the auxiliary amplifier is biased to operate in Class C mode. Advantageously, the main amplifier achieves a balance between efficiency and linearity, and the auxiliary amplifier achieves a higher efficiency.

An embodiment of the present invention provides a method for driving a transmit coil in a magnetic resonance imaging (MRI) system by a RF power module. The method comprises the steps of dividing an input RF signal into a main input signal and an auxiliary input signal, selecting each of a main amplifier and an auxiliary amplifier from a plurality of amplifiers according to an impedance Z_{L} of the transmit coil, amplifying the main input signal by the main amplifier, amplifying the auxiliary input signal by the auxiliary amplifier, adjusting current contributions from the main amplifier and the auxiliary amplifier according to the impedance Z_{L} of the transmit coil to alleviate loading mismatch condition of the main amplifier, combining the main amplified signal and the auxiliary amplified signal into an output signal, and driving the transmit coil by the output signal. The power level of the main input signal is higher than the power level of the auxiliary input signal. Each amplifier has a predetermined optimum load impedance Z_{OP}, e.g., 50Ω, into which the amplifier is designed to deliver the maximum output power.

According to one embodiment of the invention, the method further comprises the steps of generating a first current I1 flowing from a first one of the amplifiers to the transmit coil through a common node, generating a second current I2 flowing from a second one of the amplifiers to the transmit coil sequentially through an impedance transformer and the common node, and selecting the main amplifier and the auxiliary amplifier from the first and second amplifiers according to the impedance Z_{L}. The first amplifier is selected as the main amplifier and the second amplifier is selected as the auxiliary amplifier if the impedance Z_{L} is smaller than Z_{OP}. The second amplifier is selected as the main amplifier and the first amplifier is selected as the auxiliary amplifier if the impedance Z_{L} is larger than Z_{OP}.

According to yet another embodiment of the invention, a characteristic impedance Z_{TL} of the impedance transformer is substantially equal to (Z_{OP}*Z_{LH})^{1/2}. Z_{LH} represents a predetermined upper limit of a range of the impedance Z_{L}.

According to yet another embodiment of the invention, the method further comprises the steps of detecting the impedance Z_{L} of the transmit coil during a pre-scan of the MRI system, and controlling a division of the RF input signal, and bias voltages of the first and second amplifiers to adjust a current ratio between the first and second currents I1 and I2.

According to yet another embodiment of the invention, the method further comprises the step of adjusting current contributions respectively from the main amplifier and the auxiliary amplifier according to the impedance Z_{L} of the transmit coil to obtain the predetermined optimum load impedance Z_{OP} on the main amplifier.

According to yet another embodiment of the invention, the method further comprises the steps of biasing the main amplifier to operate in Class AB mode, and biasing the auxiliary amplifier to operate in Class C mode.

An embodiment of the present invention provides a magnetic resonance imaging system comprising a RF power module according to the present invention.

Various aspects and features of the disclosure are described in further detail below. And other objects and advantages of the present invention will become more apparent and will be easily understood with reference to the description made in combination with the accompanying drawings.

### DESCRIPTION OF THE DRAWINGS

The present invention will be described and explained hereinafter in more detail in combination with embodiments and with reference to the drawings, wherein:

FIG. 1 illustrates a magnetic resonance imaging system 100 according to one embodiment of the present invention.

FIG. 2 illustrates a schematic diagram of a RF power module according to one embodiment of the present invention.

FIG. 3 illustrates a detailed schematic diagram of a RF power module according to one embodiment of the present invention.

FIG. 4 illustrates a schematic diagram of a RF power module according to another embodiment of the present invention.

FIG. 5 illustrates a schematic diagram of a RF power module according to yet another embodiment of the present invention.

FIG. 6 illustrates a method for driving a transmit coil using the RF power module according to one embodiment of the present invention.

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn to scale for illustrative purposes.

### DETAILED DESCRIPTION OF THE EMBODIMENTS

Like-numbered elements in these figures are either equivalent elements or perform the same function. Elements which have been discussed previously will not necessarily be discussed in later figures if the function is equivalent.

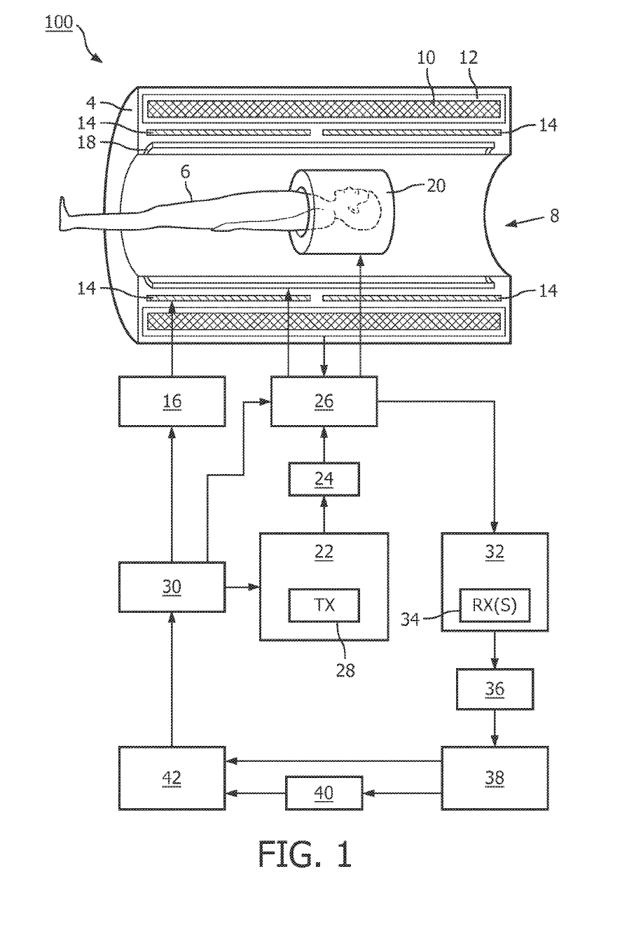

FIG. 1 illustrates a magnetic resonance imaging (MRI) system 100 that excites nuclei (e.g., associated with isotopes such as IH, 19F, 13C, 31p, etc.) within a subject, using a RF power amplifier. The system 100 includes a housing 4. A subject 6 (e.g., a human, an object, etc.) is at least partially disposed within a bore 8 of the housing 4 for one or more MRI procedures (e.g., spin echo, gradient echo, stimulated echo, etc.). A magnet 10 resides in the housing 4. The magnet 10 typically is a persistent superconducting magnet surrounded by a cryo shrouding 12. However, other known magnets (e.g., a resistive magnet, a permanent magnet, etc.) can be employed. The magnet 10 produces a stationary and substantially homogeneous main magnetic field B0 in the subject 6. As a result, the nuclei within the subject 6 preferentially align in a parallel and/or anti-parallel direction with respect to the magnetic flux lines of the magnetic field B0. Typical magnetic field strengths are about 0.5 Tesla (0.5 T), 1.0 T, 1.5 T, 3 T or higher (e.g., about 7 T).

Magnetic field gradient coils 14 are arranged in and/or on the housing 4. The coils 14 superimpose various magnetic field gradients G on the magnetic field B0 in order to define an imaging slice or volume and to otherwise spatially encode excited nuclei. Image data signals are produced by switching gradient fields in a controlled sequence by a gradient controller 16. One or more radio frequency (RF) coils or resonators are used for single and/or multi-nuclei excitation pulses within an imaging region. Suitable RF coils include a full body coil 18 located in the bore 8 of the system 2, a local coil (e.g., a head coil 20 surrounding a head of the subject 6), and/or one or more surface coils.

An excitation source 22 generates the single and/or multi-nuclei excitation pulses and provides these pulses to the RF coils 18 and/or 20 through a RF power module 24 and a switch 26. The excitation source 22 includes at least one transmitter (TX) 28.

A scanner controller 30 controls the excitation source 22 based on operator instructions. For instance, if an operator selects a protocol for acquisition of proton spectra, the scanner controller 30 accordingly instructs the excitation source 22 to generate excitation pulses at a corresponding frequency, and the transmitter 28 generates and transmits the pulses to the RF coils 18 or 20 via the RF power module 24. The single or multi-nuclei excitation pulses are fed to the RF power module 24. Conventional MRI systems typically utilize multiple amplifiers, in case more than one excitation spectrum is used.

The single or multi-nuclei excitation pulses are sent from the RF power module 24 to the coils 18 or 20 through the switch 26. The scanner controller 30 also controls the switch 26. During an excitation phase, the scanner controller 30 controls the switch 26 and allows the single or multi-nuclei excitation pulses to pass through the switch 26 to the RF coils 18 or 20, but not to a receive system 32. Upon receiving the single or multi-nuclei excitation pulses, the RF coils 18 or 20 resonate and apply the pulses into the imaging region. The gradient controller 16 suitably operates the gradient coils 14 to spatially encode the resulting MR signals.

During the readout phase, the switch 26 connects the receive system 32 to one or more receive coils to acquire the spatially encoded MR signals. The receive system 32 includes one or more receivers 34, depending on the receive coil configuration. The acquired MR signals are conveyed (serially and/or in parallel) through a data pipeline 36 and processed by a processing component 38 to produce one or more images.

The reconstructed images are stored in a storage component 40 and/or displayed on an interface 42, other display device, printed, communicated over a network (e.g., the Internet, a local area network (LAN) . . . ), stored within a storage medium, and/or otherwise used. The interface 42 also allows an operator to control the magnetic resonance imaging scanner 2 through conveying instructions to the scanner controller 30.

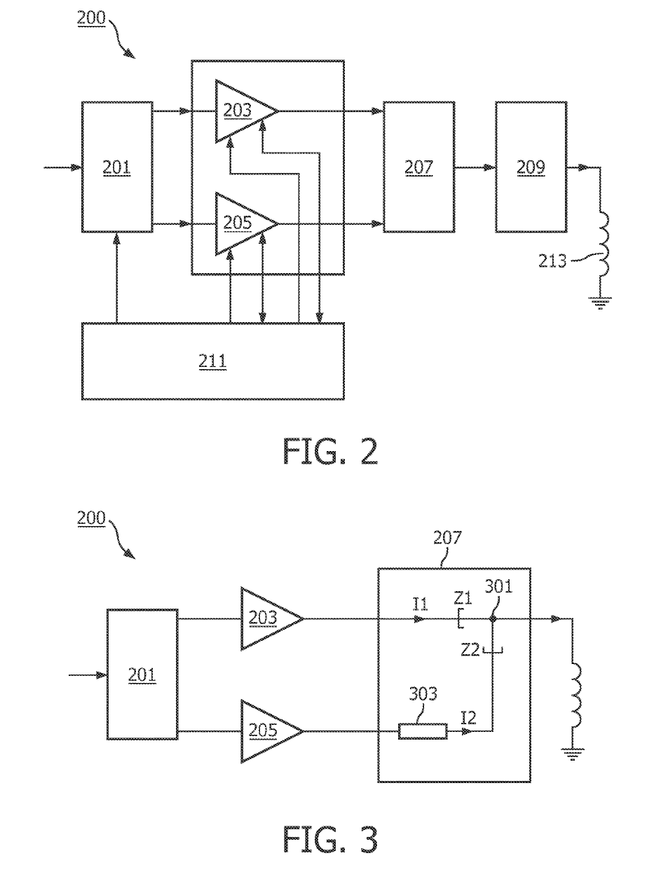

FIG. 2 illustrates a schematic diagram of a RF power module 200 according to one embodiment of the present invention. As understood, the basic function of the RF power module 200 is to amplify the power of an RF input pulse, e.g., from the transmitter 28, to output a desired power level to the transmit coil, e.g., the transmit coil 18 and/or 20. In the embodiment of FIG. 2, the RF power module 200 includes a RF input distribution network 201, an amplifier section including multiple amplifiers, e.g., a first amplifier 203 and a second amplifier 205, a signal combining network 207, a directional coupler 209 and a controller 211.

The RF input distribution network 201 receives a low magnitude RF input pulse to divide it into a first input signal and a second input signal, which are provided to the amplifier section, e.g., the parallel coupled first amplifier 203 and second amplifier 205, respectively. The first amplifier 203 and second amplifier 205 increase power levels of received RF pulse signals and provide the amplified RF pulse signals to the signal combining network 207. The signal combining network 207 combines the amplified RF pulse signals to output the desired power level for driving a transmit coil, e.g., transmit coil 213. The directional coupler 209 is further coupled to the output of the signal combining network 207 for separating out precise, proportional samples of forward and reflected signal power for internal and/or external power monitoring and fault detection. As well acknowledged by the skilled in the art, the RF input distribution network 201 typically divides the RF input pulse evenly or according to a predetermined ratio between the amplifiers in conventional MRI RF power amplifiers operating in a combined, balanced Class AB mode. However, as aforementioned, the impedance mismatch arising from the considerable loading variation on the RF transmit coil 213 tends to degrade the performance of such MRI RF power amplifiers significantly.

In the embodiment of FIG. 2, a Doherty mode is developed for the RF power module 200. More specifically, instead of even distribution of the RF input pulse or dividing the RF input pulse according to a predetermined ratio, the controller 211 controls the RF input distribution network 201 to divide the RF input pulse into a main input signal and an auxiliary input signal according to an impedance Z_{L}, of the transmit coil 213. The controller 211 further selects one of the first and second amplifiers 203 and 205 as a main amplifier to amplify the main input signal, and the other amplifier as an auxiliary amplifier to amplify the auxiliary input signal. By managing current contributions from the main amplifier and the auxiliary amplifier according to the impedance Z_{L}, the loading seen by the main amplifier, which contributes more output power, is always modulated to an impedance level that can alleviate the loading mismatch condition. Although the loading mismatch still occurs to the auxiliary amplifier, the auxiliary amplifier only delivers a relatively small portion of the output power, and thereby the effect of the loading mismatch at the auxiliary amplifier is limited or negligible. It should be acknowledged by those skilled in the art that selection of the main and auxiliary amplifiers is not necessarily through the controller 211. An alternative solution can be contemplated as long as the main and auxiliary amplifiers are selected to make different current contributions according to the impedance Z_{L} to alleviate the load mismatch condition. As an example, a multiplexer can be adopted to select the main and auxiliary amplifiers manually, e.g., by an operator, according to the impedance Z_{L}.

In one embodiment, the directional coupler 209 is used to further detect the impedance Z_{L} of the transmit coil 213 during a pre-scan of the URI system 100 and provides it to the controller 211. The controller 211 adjusts current contributions respectively from the main amplifier and the auxiliary amplifier according to the impedance Z_{L} of the transmit coil 213 to obtain the predetermined optimum load impedance Z_{OP} on the main amplifier. Advantageously, the load seen by the main amplifier, which contributes more output power, is modulated to the predetermined optimum load impedance Z_{OP}, e.g., a typical RF amplifier's 50Ω impedance, which allows the main amplifier to always operate in the load matching condition regardless of a variation in the impedance Z_{L} of the transmit coil, e.g., arising from different size and/or weight of the patients to be examined.

The proper setting of current contribution from the first and second amplifiers 203 and 205 is achieved by proper division of the RF input pulse by RF input distribution network 201 and proper biasing of the first and second amplifiers. More specifically, the controller 211 includes a feedback loop which detects a current I1 from the first amplifier 203 and a current I2 from the second amplifier 205, and controls the RF input distribution network 201 and the biasing of the first and second amplifiers 203 and 205 to adjust a current ratio between the currents I1 and I2 according to the impedance Z_{L}. The main amplifier with a greater output power contribution is biased in Class AB mode to achieve a balance between efficiency and linearity. The auxiliary amplifier with a smaller output power contribution is biased in Class C mode to achieve a higher efficiency.

In summary, the gist of the invention is to develop the Doherty mode for the RF power module 200 used in the MRI system 100. In the Doherty mode, a larger portion of the desired output power is contributed by the main amplifier, always in a lower load mismatch condition or load matching condition irrespective of the load variation in the impedance Z_{L} of the transmit coil 213, thereby causing the impact of the load mismatch to be alleviated. It would be acknowledged by those skilled in the art that the RF power module 200 may also include these and other components which are not shown herein for brevity, for example, a pre-driver and a driver (not shown) that are low-power amplifier stages for raising the power level of the small, low-power level RF input pulse from the milli-Watt range to a level high enough to drive the high-power amplifier section, e.g., the first and second amplifiers 203 and 205.

FIG. 3 illustrates a detailed schematic diagram of the RF power module 200 according to one embodiment of the present invention. In the embodiment of FIG. 3, the signal combining network 207 further comprises a common node 301 coupled to the first amplifier 203 and the transmit coil 213, and an impedance transformer 303 coupled between the second amplifier 205 and the common node 301. The first amplifier 203 forms a first amplifier path to provide the current I1 to the common node, and the second amplifier 205 and the impedance transformer 303 form a second amplifier path to provide the current I2 to the common node 301. A characteristic impedance L_{TL} of the transformer 303 is predetermined according to an equation (1),

Z_{TL}²=Z_{OP}*Z_{LH} (1)

where the impedance Z_{LH} represents a predetermined upper limit of the impedance Z_{L}, and Z_{LH} is higher than Z_{OP} but not higher than 2*Z_{OP}, that is Z_{OP}<Z_{LH}=<2*Z_{OP}.

If the impedance Z_{L}, e.g., detected during a pre-scan of the MRI system 100, is below the predetermined optimum load impedance Z_{OP} but not below Z_{OP}/2, that is Z_{OP}>=Z_{L}>=Z_{OP}/2, the first amplifier 203 is selected as the main amplifier and the second amplifier 205 is selected as the auxiliary amplifier by biasing the gate voltages of the first and second amplifiers respectively. Due to the load pull effect, the impedance Z1 seen by the first amplifier 203 is given by an equation (2),

Z1=Z_{L}*(1+I2/I1) (2)

As seen from the equation (2), for the impedance Z_{L} within Z_{OP}>Z_{L}>=Z_{OP}/2, the impedance Z_{L}, which is below the predetermined optimum load impedance Z_{OP}, can be modulated higher to be closer or equal to the predetermined optimum load impedance Z_{OP}, thereby alleviating the loading mismatch condition. Preferably, Z1 is modulated to the predetermined optimum load impedance Z_{OP} to allow the first amplifier 203 to operate in the load matching condition. In this instance, a ratio between the current contributions from the first and second amplifiers 203 and 205 can be determined according to equation (3),

I1/I2=Z_{L}/(Z_{OP}−Z_{L})

In an implementation, by properly adjusting the division of the RF input signal and the quiescent operation point of the first and second amplifiers 203 and 205, the controller 211 adjusts the current ratio between the first and second currents I1 and I2 until the predetermined current contribution ratio according to equation (3) is obtained.

For the range Z_{OP}>Z_{L}>Z_{OP}/2, the current I1 is larger than the current I2 and consequently more output power is contributed by the first amplifier 203 operating in the load matching condition. In one embodiment, the controller 211 biases the first amplifier 203, which is selected as the main amplifier in Class AB mode, to achieve a balance between efficiency and linearity. The impedance seen by the second amplifier 205 can be determined according to a combination of equations (4) and (5).

Z2′=Z_{L}*(1+I1/I2) (4)

Z2=Z_{TL}²/Z2′ (5)

For the range Z_{OP}>Z_{L}>Z_{OP}/2, the impedance Z2 seen by the second amplifier 205 is modulated to an impedance relatively higher than the predetermined optimum load impedance Z_{OP}. Given that a small portion of the output power is delivered by the second amplifier 205, the effect of the load mismatch caused hereby is limited or negligible. In one embodiment, the second amplifier 205 is biased in Class C mode to achieve a higher efficiency.

According to equation (3), when Z_{L} is equal to Z_{OP}/2, the current I1 is equal to the current I2 and both amplifiers 203 and 205 are operating in the load matching condition. When Z_{L} is equal to Z_{OP}, the current I2 is equal to zero, which means that the second amplifier 205 is disabled and all output power is contributed by the first amplifier 203.

If the impedance Z_{L}, e.g., detected during a pre-scan of the MRI system 100, is above the predetermined optimum load impedance Z_{OP} but not higher than the predetermined Z_{LH}, that is Z_{LH}>=Z_{L}>Z_{OP}, the second amplifier 205 is selected as the main amplifier and the first amplifier 203 is selected as the auxiliary amplifier by biasing the gate voltages of the first and second amplifiers respectively. Due to the load-pull effect, the impedance Z2 seen by the second amplifier 205 is determined by the combination of equations (4) and (5). Preferably, Z2 is modulated to the predetermined optimum load impedance Z_{OP} to allow the second amplifier 205 to operate in the load matching condition. In this instance, the ratio between current contributions from the first and second amplifiers 203 and 205 can be determined according to equation (6),

I1/I2=(Z_{LH}−Z_{L})/Z_{L} (6)

In an implementation, by properly adjusting the division of the RF input signal and the quiescent operation point of the first and second amplifiers 203 and 205, the controller 211 adjusts the current ratio between the first and second currents I1 and I2 until the predetermined current contribution ratio according to equation (6) is obtained.

For the range Z_{LH}>Z_{L}>Z_{OP}, the current I1 is smaller than the current I2, given that Z_{OP}<Z_{LH}=<2*Z_{OP}, and consequently more output power is contributed by the second amplifier 205 operating in the load matching condition. In one embodiment, the controller 211 biases the second amplifier 205 which is selected as the main amplifier in Class AB mode to achieve a balance between efficiency and linearity. The impedance seen by the first amplifier 203 can be determined according to the equation (2). For the range Z_{LH}>Z_{L}>Z_{OP}, the impedance Z1 seen by the first amplifier 203 is modulated to an impedance higher than the predetermined optimum toad impedance Z_{OP}. Given that a small portion of the output power is delivered by the first amplifier 203, the effect of the load mismatch caused hereby is limited or negligible. In one embodiment, the first amplifier 203 is biased in Class C mode to achieve a higher efficiency.

According to equation (6), when Z_{L} is equal to Z_{LH}, the current I1 is equal to zero which means the first amplifier 203 is disabled and all output power is contributed by the second amplifier 205.

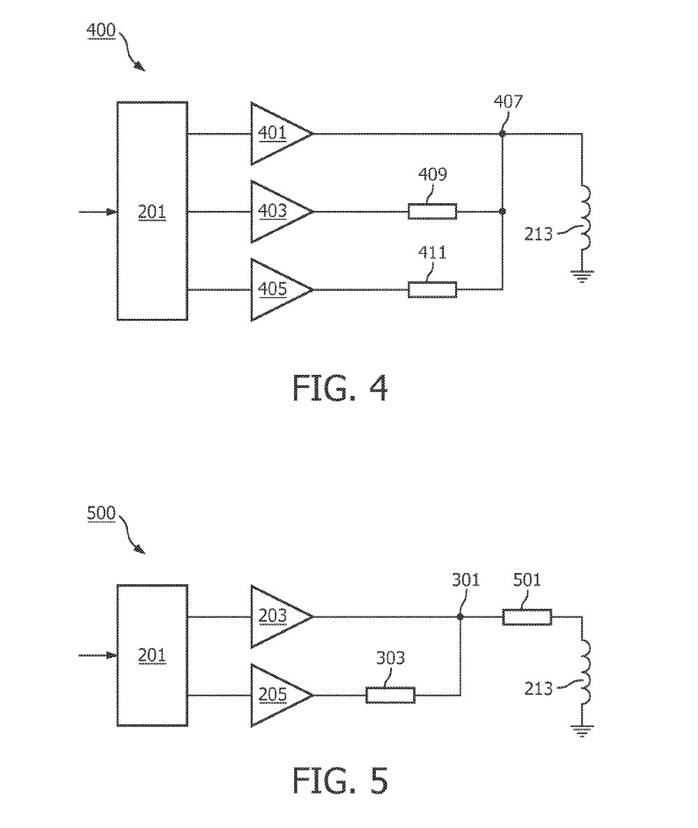

FIG. 4 illustrates a schematic diagram of a RF power module 400 according to another embodiment of the present invention. In the embodiment of FIG. 4, the amplifier section includes three amplifiers 401, 403 and 405. The signal combining network includes a common node 407 coupled to the amplifier 401, the impedance transformer 409 coupled between the amplifier 403 and the common node 407, and the impedance transformer 411 coupled between the amplifier 405 and the common node 407. A characteristic impedance Z_{TL1} of the impedance transformer 409 and a characteristic impedance Z_{TL2} of the impedance transformer 411 are given respectively by equations (7) and (8)

Z_{TL1}²=Z_{OP}*Z_{LH1} (7)

Z_{TL2}²=Z_{OP}*Z_{LH2} (8)

where Z_{OP}<Z_{LH1}=<2*Z_{OP}, and Z_{LH1}<Z_{LH2}<=2*Z_{OP}.

According to the configuration of FIG. 4, more impedance ranges Z_{OP}<Z_{L}<=Z_{LH1} and Z_{LH1}<Z_{L}<=Z_{LH2} are provided for the impedance Z_{L} of the transmit coil when Z_{L} is higher than Z_{OP}. For Z_{OP}<Z_{L}<=Z_{LH1}, the amplifier 403 is selected as the main amplifier, as discussed with reference to FIG. 3, and the amplifier 405 is disabled. For Z_{LH1}<Z_{L}<=Z_{LH2}, the amplifier 405 is selected as the main amplifier, as discussed with reference to FIG. 3, and the amplifier 403 is disabled. Owing to the multiple impedance ranges, on the one hand, it is apparent that the RF power module 400 can deliver the desired output power, over a wider impedance range, to the transmit coil 213; on the other hand, the RF power module 400 can select one of the amplifiers delivering a greater power contribution as the main amplifier, which further enhances performance of the RF power amplifier. For example, assuming Z_{LH1}=1.5*Z_{OP}, Z_{LH2}=2*Z_{OP}, and Z_{L}=1.3*Z_{OP}, the amplifier 403 is selected as the main amplifier. According to equation (6), the current ratio between the current I1 and current I2 is 2/13. While, if only the amplifier 405 is available for operating as the main amplifier, the current ratio between the current I1 and the current I2 is 7/13 according to equation (6). Obviously, when operating in the load matching condition as the main amplifier, the amplifier 403 contributes more output power than the amplifier 405, and therefore it is preferable to select the amplifier 403 as the main amplifier.

It is recognized by those skilled in the art that the number of amplifiers is not necessarily limited to 3. In implementations, the number of amplifiers cart be carefully selected to achieve a balance between performance and cost.

FIG. 5 illustrates a schematic diagram of a RF power module 500 according to yet another embodiment of the present invention. In the embodiment of FIG. 5, an additional impedance transformer 501 is coupled between the common node 301 and the transmit coil 213, which is configured to transform a wider range of the load variation into a reduced range more favorable for the RF power module 300 or 400 as discussed above.

As aforementioned with reference to FIG. 3, Z_{LH}, the predetermined upper limit of the impedance Z_{L}, is higher than Z_{OP} but not higher than 2*Z_{OP}, that is Z_{OP}<Z_{LH}<2*Z_{OP}. However, the impedance Z_{L} of the transmit coil may vary in a wider range [Z_{OP}, 4*Z_{OP}]. In this instance, the impedance transformer 501 with carefully selected characteristic impedance Z_{TL}′ can transform the wider range to the reduced range. For example, the characteristic impedance Z_{TL}′ of the impedance transformer 501 can be given according to equation (9),

Z_{TL}′=Z_{OP}*2^{1/2} (9)

With the characteristic impedance Z_{TL}′, the impedance range [Z_{OP}, 4*Z_{OP}] is transformed to [Z_{OP}/2, 2*Z_{OP}], which is a range more favorable for the RF power amplifier as discussed with reference to FIG. 3.

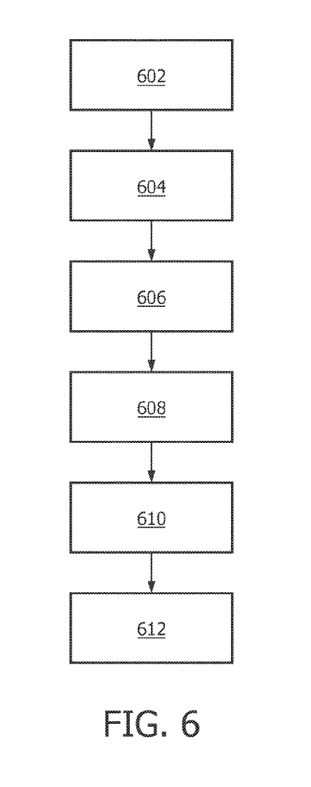

FIG. 6 illustrates a method for driving a transmit coil in a magnetic resonance imaging system according to one embodiment of the present invention. FIG. 6 is described in combination with FIGS. 2-5.

In step 602, an input RF signal is divided into a main input signal and an auxiliary input signal. In the embodiment of FIG. 2, the RF distribution network 201 divides the RF input signal into the main input signal and auxiliary input signal under control of the controller 211.

In step 604, a main amplifier and an auxiliary amplifier are selected from a plurality of amplifiers according to an impedance Z^{L} of the transmit coil. Each amplifier has a predetermined optimum load impedance Z_{OP}. In the embodiment of FIG. 3, the first amplifier 203 is selected as the main amplifier for the impedance range Z_{OP}>=Z_{L}>=Z_{OP}/2, and the second amplifier 205 is selected as the main amplifier for the impedance range Z_{LH}>=Z_{L}>Z_{OP}. In the embodiment of FIG. 4, the amplifier 401 is selected as the main amplifier for the impedance range Z_{OP}>=Z_{L}>=Z_{OP}/2, the amplifier 403 is selected as the main amplifier for the impedance range Z_{LH1}>=Z_{L}>Z_{OP}, and the amplifier 405 is selected as the main amplifier for the impedance range Z_{LH2}>=Z_{L}>L_{LH1}.

In step 606, the main input signal is amplified by the main amplifier.

In step 608, the auxiliary input signal is amplified by the auxiliary amplifier.

In step 610, the main amplified signal and the auxiliary amplified signal are combined into an output signal. In the embodiment of FIG. 3, the signal combination network including the common node 301 and the impedance transformer 303 combines the amplified main and auxiliary signals into the output signal. In the embodiment of FIG. 4, the signal combination network including the common node 407 and the impedance transformers 409 and 411 combines the amplified main and auxiliary signals into the output signal.

In step 612, the transmit coil is driven by the output signal.

The invention has been described with reference to the preferred embodiments. Modifications and alterations may occur to others upon reading and understanding the preceding detailed description. It is intended that the invention be constructed as including all such modifications and alterations insofar as they come within the scope of the appended claims or the equivalents thereof.

1. A radio frequency (RF) power module for driving a transmit coil in a magnetic resonance imaging (MRI) system adapted to various load conditions, the RF power module comprising:
an RF input distribution network configured to divide an input RF signal into a main input signal provided to a main amplifier and an auxiliary input signal provided to an auxiliary amplifier;
a plurality of amplifiers coupled to the RF input distribution network and configured to provide output power to the transmit coil, wherein one of the amplifiers is selected as the main amplifier according to an impedance Z_{L} of the transmit coil and another one of the amplifiers is selected as the auxiliary amplifier according to the impedance Z_{L} of the transmit coil to obtain a portion of the output power contributed by the main amplifier larger than or equal to a portion of the output power contributed by the auxiliary amplifier, wherein a loading level of the main amplifier is modulated to alleviate loading mismatch condition of the main amplifier by adjusting current contributions from the main amplifier and the auxiliary amplifier according to the impedance Z_{L} of the transmit coil; and
a signal combining network configured to combine a main amplified signal provided by the main amplifier and an auxiliary amplified signal provided by the auxiliary amplifier into an output signal to drive the transmit coil.

2. The RF power module of claim 1, further comprising:
a controller coupled to the RF input distribution network and the amplifiers and configured to adjust the current contributions respectively from the main amplifier and the auxiliary amplifier according to the impedance Z_{L} of the transmit coil to obtain the loading level of the main amplifier equal to a predetermined optimum load impedance Z_{OP} of each amplifier of the RF power module.

3. The RF power module of claim 2, wherein the amplifiers further comprise:
a first amplifier configured to provide a first current I1 to the transmit coil through a common node; and
a second amplifier configured to provide a second current I2 to the transmit coil sequentially through an impedance transformer and the common node, wherein the impedance transformer and the common node form the signal combining network, wherein each of the main amplifier and the auxiliary amplifier is selected from the first amplifier and the second amplifier according to the impedance Z_{L} of the transmit coil.

4. The RF power module of claim 3, wherein a characteristic impedance Z_{TL} of the impedance transformer is predetermined according to Z_{TL}=(Z_{OP}*Z_{LH})^{1/2}, and wherein Z_{LH} represents a predetermined upper limit of the input impedance Z_{L}.

5. The RF power module of claim 4, wherein the first amplifier is selected as the main amplifier and the second amplifier is selected as the auxiliary amplifier if the impedance Z_{L} is within an impedance range Z_{OP}/2<Z_{L}=<Z_{OP}, and wherein the second amplifier is selected as the main amplifier and the first amplifier is selected as the auxiliary amplifier if the impedance Z_{L} is within an impedance range Z_{OP}<Z_{L}=<Z_{LH}.

6. The RF power module of claim 3, further comprising:
a directional coupler coupled to the transmit coil and used to detect the impedance Z_{L} of the transmit coil during a pre-scan of the MRI system, wherein the controller is configured to control the division of the RF input signal into the main signal and the auxiliary signal and bias voltages of the first and second amplifiers to adjust a current ratio between the current I₁ and the current I₂ according to the detected impedance Z_{L}, thereby alleviating the loading mismatch condition of the main amplifier.

7. The RF power module of claim 1, wherein the main amplifier is biased to operate in Class AB mode and the auxiliary amplifier is biased to operate in Class C mode.

8. A method for driving a transmit coil in a magnetic resonance imaging (MRI) system adapted to various load conditions by a RF power module, the method comprising:
dividing an input RF signal into a main input signal for a main amplifier and an auxiliary input signal for an auxiliary amplifier;
selecting one amplifier from a plurality of amplifiers as the main amplifier according to an impedance Z_{L} of the transmit coil;
selecting another amplifier from the plurality of amplifiers as the auxiliary amplifier according to the impedance Z_{L} of the transmit coil, wherein a portion of output power contributed by the main amplifier is larger than or equal to a portion of the output power contributed by the auxiliary amplifier;
amplifying the main input signal by the main amplifier;
amplifying the auxiliary input signal by the auxiliary amplifier;
adjusting current contributions from the main amplifier and the auxiliary amplifier according to the impedance Z_{L} of the transmit coil to alleviate loading mismatch condition of the main amplifier;
combining the main amplified signal and the auxiliary amplified signal into an output signal; and
driving the transmit coil by the output signal.

9. The method of claim 8, further comprising:
generating a first current I1 flowing from a first one of the amplifiers to the transmit coil through a common node;
generating a second current I2 flowing from a second one of the amplifiers to the transmit coil sequentially through an impedance transformer and the common node; and
selecting the main amplifier and the auxiliary amplifier from the first and second amplifiers according to the impedance Z_{L}.

10. The method of claim 9, further comprising:
predetermining a characteristic impedance Z_{TL} of the impedance transformer according to Z_{TL}=(Z_{OP}*Z_{LH})^{1/2}, wherein Z_{LH} represents a predetermined upper limit of the impedance Z_{L} and Z_{OP} represents a predetermined optimum load impedance Z_{OP} of each amplifier of the RF power module.

11. The method of claim 10, further comprising one of the following steps:
selecting the first amplifier as the main amplifier and the second amplifier as the auxiliary amplifier if the impedance Z_{L} is within an impedance range Z_{OP}/2<Z_{L}=<Z_{OP}; and
selecting the second amplifier as the main amplifier and the first amplifier as the auxiliary amplifier if the impedance Z_{L} is within an impedance range Z_{OP}<Z_{L}=<Z_{LH}. 1 2.(currently amended) The method of claim 9, further comprising:
detecting the impedance Z_{L} of the transmit coil during a pre-scan of the MRI system; and
controlling the division of the RF input signal into the main signal and the auxiliary signal and bias voltages of the first and second amplifiers to adjust a current ratio between the first and second currents I1 and I2 based on the detected impedance Z_{L}, thereby alleviating the loading mismatch condition of the main amplifier.

13. The method of claim 8, further comprising:
adjusting current contributions respectively from the main amplifier and the auxiliary amplifier according to the impedance Z_{L} of the transmit coil to obtain the predetermined optimum load impedance Z_{OP} on the main amplifier.

14. The method of claim 8, further comprising:
biasing the main amplifier to operate in Class AB mode; and
biasing the auxiliary amplifier to operate in Class C mode.

145. A magnetic resonance imaging system comprising a radio frequency (RF) power module according to claim 1.
